(19) United States
(12) Patent Application Publication
(10) Pub. No.: US 2024/0234359 A9
(43) Pub. Date: Jul. 11, 2024

(54) Semiconductor Device and Manufacturing Method for Semiconductor Device

(71) Applicant: Hitachi Astemo, Ltd., Hitachinaka-shi, Ibaraki (JP)

(72) Inventors: Osamu IKEDA, Tokyo (JP); Naoki SAKURAI, Hitachinaka-shi (JP); Takayuki OSHIMA, Hitachinaka-shi (JP); Takuma HAKUTO, Hitachinaka-shi (JP)

(21) Appl. No.: 18/566,303

(22) PCT Filed: Feb. 21, 2022
(86) PCT No.: PCT/JP2022/007041

§ 371 Date: Dec. 1, 2023

(30) Foreign Application Priority Data
Jun. 9, 2021 (JP) 2021-096947

(51) Int. Cl. H01L 23/00

(52) U.S. Cl. CPC H01L 24/29; H01L 24/27; H01L 24/32; H01L 24/48; H01L 2224/278; H01L 2224/29111; H01L 2224/29147; H01L 2224/29155; H01L 2224/32245; H01L 2224/4846

(57) ABSTRACT

A semiconductor device includes a semiconductor element having an Ni—V electrode and a conductor, the semiconductor element and the conductor being bonded via Sn-based lead-free solder. In the semiconductor device, an Sn—V compound layer and an (Ni, Cu)3Sn4 compound layer adjacent to the Sn—V compound are formed adjacent to an interface between the semiconductor element and the Sn-based lead-free solder. A manufacturing method for a semiconductor device according to the present invention includes: causing the Sn-based lead-free solder and the Ni—V electrode to react with each other to form an Sn—V layer and an (Ni, Cu)3Sn4 compound layer; and following formation of the Sn—V layer, leaving an unreacted layer of the Ni—V electrode, the unreacted layer having not reacted with the Sn-based lead-free solder, intact.

### TECHNICAL FIELD

The present invention relates to a semiconductor device and a manufacturing method for a semiconductor device.

### BACKGROUND ART

Use of lead in electronic control devices incorporated in automobiles is regulated by the restriction of hazardous substances directive (RoHS directive) and the end-of-life vehicles directive (ELV directive). In comply with these regulations, using lead-free solder as solder for bonding work related to the devices has been promoted. For example, lead-free solder of a composition of Sn-3Ag-0.5Cu, that is, lead-free solder composed mainly of Sn (tin), Ag (silver), and Cu (copper) is now in wide use.

A nickel (Ni) electrode, which is bonded to solder, is used as an electrode of a semiconductor element of an electronic control device, and this nickel (Ni) electrode is formed by sputtering in many cases. Among various types of sputtering, in recent years, magnetron sputtering capable of faster and highly efficient film formation has emerged as the mainstream of sputtering processes. When an Ni electrode is formed by this magnetron sputtering, there arises a problem that pure Ni with strong magnetism is difficult to control. For this reason, Ni—V, a material created by adding V (vanadium) to Ni, is used as a material making up an electrode film. Hence bonding by lead-free solder, which is highly reliable in bonding with an Ni—V electrode, is required for an inverter.

As background art of the present invention, the following Patent Literature 1 describes a technique according to which a Cu film is formed on an Ni—V electrode and is bonded by Sn-based lead-free solder, at which, by causing Cu to completely react with Sn to precipitate a (Cu, Ni)6Sn5 compound on the Ni—V electrode, reaction between the Ni—V electrode and the Sn-based lead-free solder is suppressed to reduce time-dependent changes in a bonding interface relative to temperature changes under a service environment.

### CITATION LIST

### Patent Literature

PTL 1: JP 4656275 B2

### SUMMARY OF INVENTION

### Technical Problem

According to the method described in Patent Literature 1, because no Sn—V compound layer is formed, the strength of a bonding portion interface remains low, which may impair the reliability of the semiconductor device. In addition, when a large shear stress develops on a bonding portion, a creep void is created in the vicinity of the bonding portion interface, in which case the reliability of the device may be impaired further. An object of the present invention, which has been conceived in view of the above problems, is to provide a semiconductor device and a manufacturing method for a semiconductor device that improve bonding reliability.

### Solution to Problem

A semiconductor device according to the present invention is a semiconductor device including a semiconductor element having an Ni—V electrode and a conductor, the semiconductor element and the conductor being bonded via Sn-based lead-free solder. In the semiconductor device, an Sn—V compound layer and an (Ni, Cu)3Sn4 compound layer or an Ni3Sn4 compound layer adjacent to the Sn—V compound are formed adjacent to an interface between the semiconductor element and the Sn-based lead-free solder.

A manufacturing method for a semiconductor device according to the present invention is a manufacturing method for a semiconductor device by which a semiconductor element having an Ni—V electrode is bonded to a conductor by Sn-based lead-free solder. The manufacturing method includes: causing the Sn-based lead-free solder and the Ni—V electrode to react with each other to form an Sn—V layer and an (Ni, Cu)3Sn4 compound layer or an Ni3Sn4 compound layer at a location adjacent to an interface between the semiconductor element and the Sn-based lead-free solder; and, following formation of the Sn—V layer, leaving an unreacted layer of the Ni—V electrode, the unreacted layer having not reacted with the Sn-based lead-free solder, intact.

### Advantageous Effects of Invention

According to the present invention, a semiconductor device and a manufacturing method for a semiconductor device that improve bonding reliability can be provided.

### BRIEF DESCRIPTION OF DRAWINGS

FIG. 1 is a schematic view of dissociation of an intermetallic compound at a reaction portion interface between a semiconductor element and Sn-based lead-free solder.

FIG. 2 is a schematic view of creep voids at the reaction portion interface between the semiconductor element and the Sn-based lead-free solder.

FIG. 3 is a schematic view of a mechanism of formation of an intermetallic compound layer of a precipitation type according to a conventional technique.

FIG. 4 is a schematic diagram of a mechanism of formation of an intermetallic compound by reaction between an Ni electrode and the Sn-based lead-free solder.

FIG. 5 is a schematic view of reaction transitions of reaction between an Ni—V electrode and the Sn-based lead-free solder.

FIG. 6 is a graph showing a relationship between an (Ni, Cu)—Sn compound and a creep void formation rate at a reaction portion interface.

FIG. 7 is a graph showing a relationship between a temperature holding time for holding bonding portion temperature at 150° C. and the thickness of the Ni—V electrode that disappears.

FIG. 8 is a schematic view of a semiconductor device according to one embodiment of the present invention.

FIG. 9 depicts a modification of the semiconductor device shown in FIG. 8.

FIG. 10 is a table of examples according to the one embodiment of the present invention, the examples being subjected to a test under individual test conditions.

FIG. 11 is a table of comparative examples according to the one embodiment of the present invention, the comparative examples being subjected to a test under individual test conditions.

Embodiments of the present invention will hereinafter be described with reference to the drawings. The following description and drawings are exemplary one for explanation of the present invention, and, to make the explanation clear, will be omitted or simplified when necessary. The present invention can be implemented in various forms different from embodiments described herein. Unless otherwise specified, each constituent element of a single form and that of a plural form are both applicable.

The positions, sizes, shapes, ranges, and the like of constituent elements shown in the drawings are those for facilitating understanding of the invention and therefore may not represent the actual positions, sizes, shapes, ranges, and the like of the same. The present invention, therefore, is not necessarily limited by positions, sizes, shapes, ranges, and the like shown in the drawings.

### Comparison with Prior Art—One Embodiment of the Present Invention

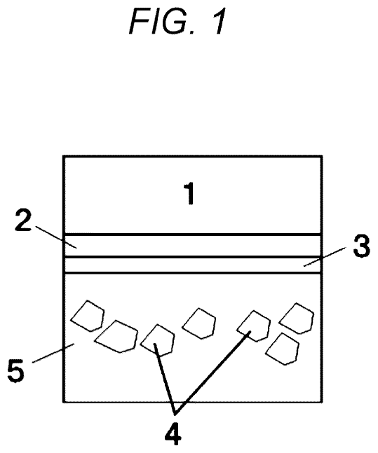

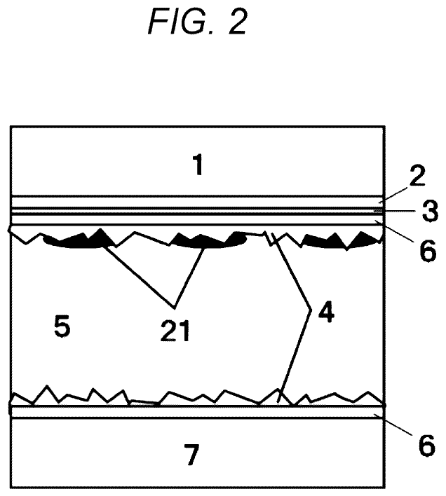

FIG. 1 is a schematic view of dissociation of an intermetallic compound at a reaction portion interface between a semiconductor element having an Ni electrode and Sn-3Ag-0.5Cu solder (Sn-based lead-free solder). FIG. 2 is a schematic view of creep voids at a bonding portion between the semiconductor element and the Sn-based lead-free solder.

To allow a semiconductor element 1 and Sn-3Ag-0.5Cu solder 5 to react well with each other, it is necessary to react the solder 5 with an Ni-based electrode formed on the semiconductor element 1 by sputtering. When the semiconductor element 1 and the Sn-3Ag-0.5Cu solder 5 react with each other, however, reaction between the solder 5 and the Ni-based electrode may proceed excessively, in which case, an (Ni, Cu)3Sn4 compound 4, which is created as a result of reaction between the Ni-based electrode formed on the semiconductor element 1 and the solder 5, separates from a reaction portion interface (a layer made up of an Al-based electrode 2 and a Ti-based electrode 3), as shown in FIG. 1.

In such an interface structure, when a semiconductor device including an Ni—V electrode chip is used under a service environment at 150° C., the risk of separation of an interface portion increases, which leads to difficulty in maintaining a bonding condition of the device and may cause damage to the reliability of the device.

As shown in FIG. 2, in a case where bonding is performed using an Ni—V electrode 7, the Ni—V electrode 7 reacts with Sn-based lead-free solder 9 faster than a case where an Ni-based electrode 6 reacts with the Sn-based lead-free solder 9 for bonding, and therefore a concern of a further increase in the risk of bonding separation arises. In addition, under the service environment at 150° C., when a large shear stress is applied to a bonding portion between the Ni-based electrode 6 and the semiconductor element 1, creep voids 21 develop in the vicinity of a compound 4 on a bonding portion interface and development of these void 21 is facilitated under a service environment at 150° C. or higher, which may damage the reliability of the device.

The voids 21 formed in the vicinity of an interface between the solder 5 and the intermetallic compound 4 shows a tendency that when the intermetallic compound 4 is thin, the voids 21 are readily formed because of a greater shear stress applied to the intermetallic compound 4. This leads to an understanding that such development of the voids 21 and bonding separation in the device happen, depending on the shape of the intermetallic compound 4.

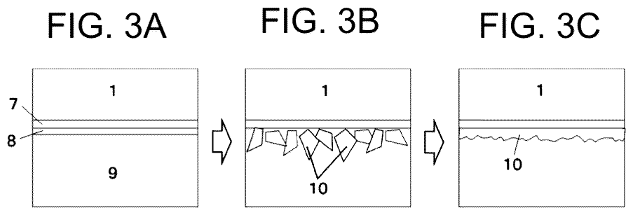

FIG. 3 is a schematic view of a mechanism of formation of an intermetallic compound layer of a precipitation type according to a conventional technique.

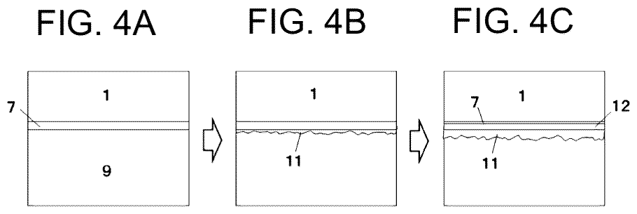

According to the conventional technique, a Cu film 8 is formed adjacent to an Ni—V electrode 7 (FIG. 3(a)), and when the Cu film 8 reacts with the Sn-based lead-free solder 9, a Cu6Sn5-based compound 10 is formed (FIG. 3(b)). This compound 10 precipitates on the Ni—V electrode 7, thus forming a layer of the intermetallic compound 10 on a reaction portion interface (FIG. 3(c)). Because the metal compound layer 10 of FIG. 3 has bonding strength lower than that of a metal compound layer 11 of FIG. 4, which will be described later, the metal compound layer 10 provides the device with lower bonding strength and therefore may damage the reliability of the device.

FIG. 4 is a schematic diagram of a mechanism of formation of an intermetallic compound by reaction between an Ni—V electrode and the Sn-based lead-free solder. In FIG. 4, the mechanism is described using the Sn-based lead-free solder containing no Cu.

As shown in FIG. 4, reaction between the Ni—V electrode 7 and the Sn-based lead-free solder 9 forms a layer of an Ni3Sn4-based compound 11 (FIG. 4(b)) and a layer of an Sn—V compound 12 (FIG. 4(c)), which are reaction layers. FIG. 4 is different from FIG. 3 in that an intermetallic compound layer in FIG. 4 is an intermetallic compound layer that has been grown as the Ni3Sn4-based compound 11 and the Sn—V compound layer 12 are formed. This forming method is adopted in the present invention.

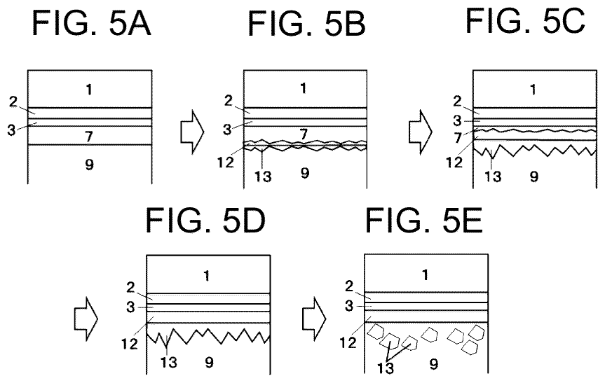

FIG. 5 is a schematic view of reaction transitions of reaction between an Ni—V electrode and the Sn-based lead-free solder.

As shown in reaction transitions of FIGS. 5(a) to 5(d), the semiconductor element 1 having the Ni—V electrode 7 with the electrodes 2 and 3 interposed between the semiconductor element 1 and the Ni—V electrode 7 and the Sn-based lead-free solder 9 are caused to react with each other. This forms the Sn—V compound layer 12 on a reaction portion interface and forms a layer of an (Ni, Cu)3Sn4 compound 13 adjacent to the Sn—V compound 12 as well, thereby offering the sufficient bonding strength of the device. As a result, the reliability of the device under the service environment at 150° C. can be ensured. When the Sn-based lead-free solder is the one containing no Cu, the layer of the (Ni, Cu)3Sn4 compound 13 is a layer of an Ni3Sn4-based compound.

However, as shown in FIG. 5(e), if reaction between the semiconductor element 1 and the Sn-based lead-free solder 9 proceeds excessively, the layer of the (Ni, Cu)3Sn4 compound 13 separates away from the Sn—V compound 12 on the reaction portion interface. Such a case raises a possibility that, under the service environment at 150° C., the Sn—V compound 12 and the Sn-based lead-free solder 9 may separate at an interface between them or a crack caused by thermal impact may run straight through the interface. In this state, the service life of the device gets shorter, which damages the reliability of the device. To prevent this, the present invention offers a feature for maintaining a stage shown in FIG. 5(d).

Specifically, as shown in FIG. 5(c), by leaving a portion of Ni—V layer 7 that has not reacted with the Sn-based lead-free solder 9 as it is, maintaining bonding with the adjacent Ti layer 3 becomes easy. This offers the device with higher bonding reliability under the service environment at 150° C.

The layer of the (Ni, Cu)3Sn4 compound 13 adjacent to the layer of the Sn—V compound 12 along the entire part thereof offers higher reliability than in a case of being adjacent to a part of the Sn—V compound 12.

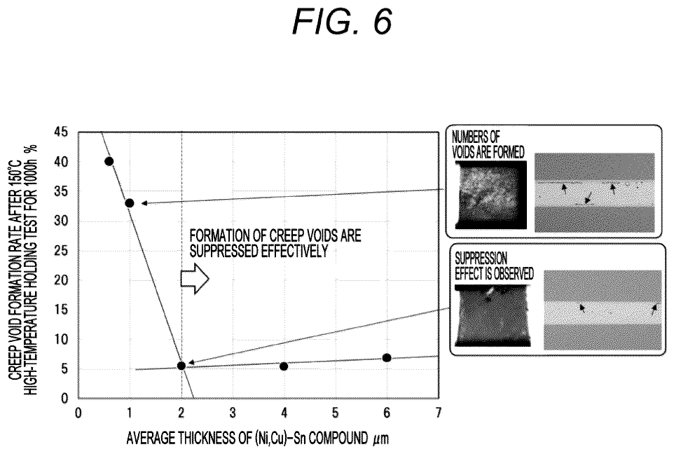

FIG. 6 is a graph showing a relationship between an (Ni, Cu)—Sn compound and a creep void formation rate at a reaction portion interface.

How the voids 21 develop in the vicinity of the reaction portion interface varies depends on the thickness of the layer of the (Ni, Cu)3Sn4 compound 13 formed on the reaction portion interface. FIG. 6 shows results of a creep test carried out at 150° C. such that a weight of 600 g is attached to a sample bonded to an Ni-plated Cu plate, using the Sn-3Ag-0.5Cu solder 5, in a 5 mm by 5 mm by 1 mm area.

As indicated by the test results of FIG. 6, it has been found that when the average thickness of the Ni3Sn4 compound layer formed on a bonding portion interface is smaller than 2 μm, a large number of voids 21 are created and that when the average thickness is 2 μm or more, formation of the voids 21 is suppressed. This leads to a conclusion that determining the thickness of the layer of the (Ni, Cu)3Sn4 compound 13 to be 2 μm or more ensures the reliability of the device under the service environment at 150° C.

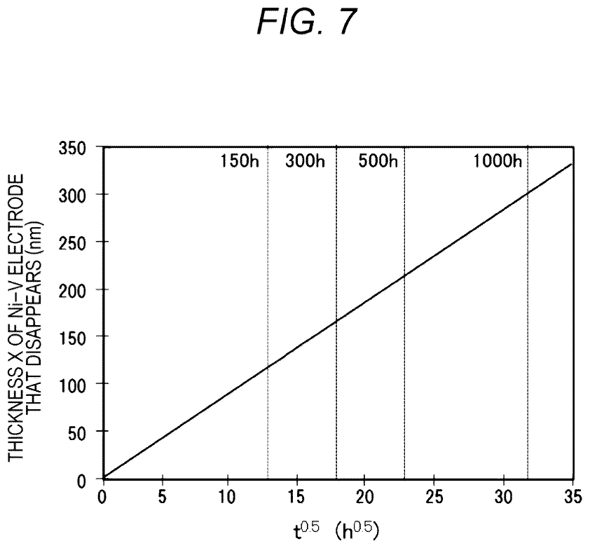

FIG. 7 is a graph showing a relationship between a temperature holding time for holding a bonding portion temperature under the service environment at 150° C. and the thickness of the Ni—V electrode that disappears.

The graph of FIG. 7 shows the thickness of the Ni—V electrode that disappears when a sample bonded to a Cu lead Ni-plated with the semiconductor element having the Ni—V electrode, using the Sn-3Ag-0.5Cu solder, is subjected to a 150° C. high-temperature holding test for 1000 h (hours). The horizontal axis of the graph represents time to the power of 0.5, and 1000 h is a reference value corresponds to 10-year guarantee of an automobile.

The test results demonstrate that when the sample is held for 1000 h under the service environment at 150° C., the Ni—V electrode of 300 nm in thickness disappears. This indicates that, to achieve higher reliability, it is desirable to adopt a structure in which at least the unreacted Ni—V electrode of 300 nm in thickness is left intact at the point of time of reaction. To leave the unreacted Ni—V electrode of 300 nm in thickness intact, it is desirable to use a semiconductor element having the Ni—V electrode with a pre-reaction thickness of 700 nm or more.

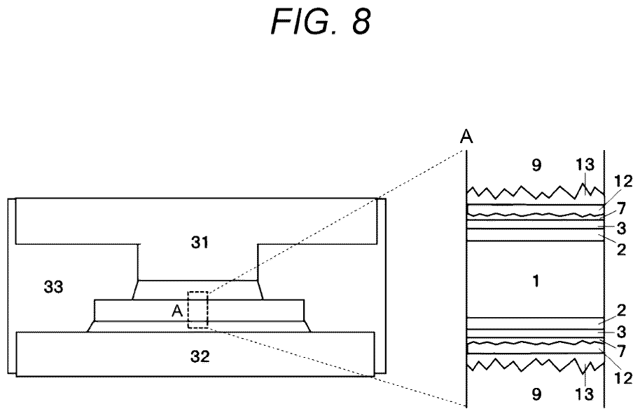

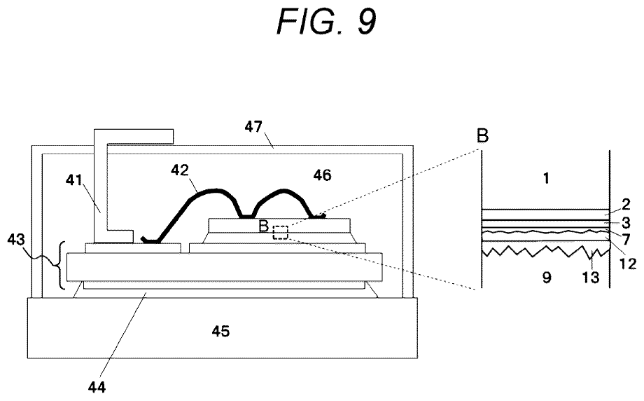

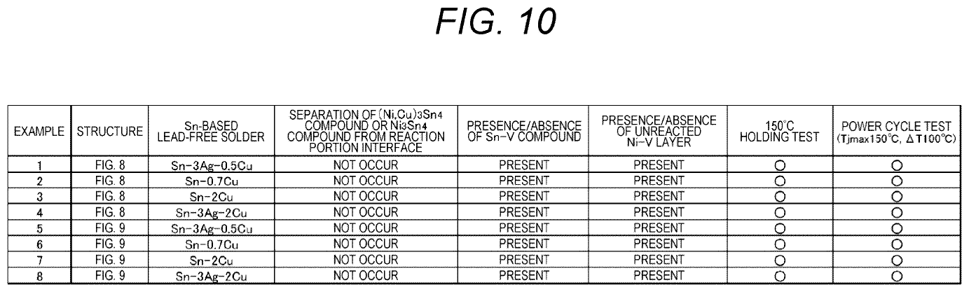

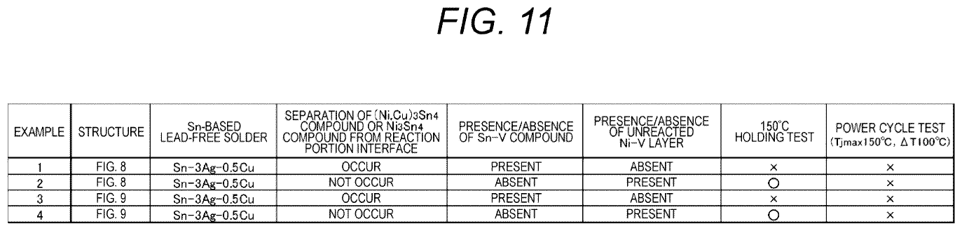

FIG. 8 is a schematic view of a semiconductor device according to one embodiment of the present invention. FIG. 9 depicts a modification of the semiconductor device shown FIG. 8. A table of FIG. 10 is a table of examples according to the one embodiment of the present invention, the examples being subjected to a test under individual test conditions, and a table of FIG. 11 is a table of comparative examples according to the one embodiment of the present invention, the comparative examples being subjected to a test under individual test conditions.

First to fourth examples of FIG. 10, to which the present invention is applied, will be described with reference to FIG. 8. It should be noted that the present invention has been applied to the first to fourth examples of the table of FIG. 10, with the composition of the Sn-based lead-free solder 9 being varied for each of the first to fourth examples, under a condition that separation of the layer of the (Ni, Cu)3Sn4 compound 13 from the interface does not occur, that the Sn—V compound layer is present, and that the unreacted Ni—V layer is not present. When the Sn-based lead-free solder 9 contains no Cu, the (Ni, Cu)3Sn4 compound is an Ni3Sn4-based compound.

The Sn-based lead-free solder 9 is supplied to a solder deposition position of Cu collector side lead frames 31 and 32 having roughened Ni plating (enlarged view A). On the Sn-based lead-free solder 9, the semiconductor element 1 having the Ni—V electrode 7 of 800 nm in thickness on both sides thereof is mounted, and the semiconductor element 1 and the lead frames 31 and 32 are bonded. Then, the Sn-based lead-free solder 9 is further supplied to an electrode on the upper surface of the bonded semiconductor element 1.

This process creates a structure which has a layer of the (Ni, Cu)3Sn4 compound 13 of 2 μm or more in average thickness that is adjacent to the Sn—V layer 12 formed by reaction as the unreacted Ni—V layer 7 of 300 nm or more in average thickness is left intact at a bonding portion of the semiconductor element 1. Thereafter, resin sealing 33 is performed by a transfer molding process to fabricate a semiconductor device.

The semiconductor device fabricated in this manner has been subjected to 50000 cycles of a power cycle test under conditions of a 150° C. high-temperature holding test for 1000 h, Tjmax150° C., and ΔTj 100° C. (FIG. 10). At the test, a case of a decrease in a bonding area of the device after the test being within 10% is evaluated as “o”, while a case of the bonding area of the device decreasing more than 10% is evaluated as “x”. This deterioration in bonding is confirmed by observation of an ultrasonic image and cross-sections.

As a result, in all of the first to fourth examples, any degrading phenomenon, such as separation and creep void formation, has been not found at a reaction portion after the reliable test. Hence it has been confirmed that the semiconductor device has sufficient bonding reliability.

Fifth to eight examples of FIG. 10, to which the present invention is applied, will then be described with reference to FIG. 9. In the same manner as in the case of the first to fourth examples, the present invention has been applied to the fifth to eighth examples of the table of FIG. 10, with the composition of the Sn-based lead-free solder 9 being varied for each of the fifth to eight examples, under a condition that separation of the layer of the (Ni, Cu)3Sn4 compound 13 from the interface does not occur, that the Sn—V compound layer is present, and that the unreacted Ni—V layer is not present. When the Sn-based lead-free solder 9 contains no Cu, the (Ni, Cu)3Sn4 compound is an Ni3Sn4-based compound.

A sheet of Sn-based lead-free solder 44 is placed on a heat-dissipating base 45, a ceramic substrate 43 is stacked on the Sn-based lead-free solder 44, a sheet of Sn-based lead-free solder 9 is placed on the substrate 43, and the semiconductor element 1 is placed on the Sn-based lead-free solder 9 and is heated to be bonded. Following bonding of the semiconductor element 1, an aluminum wire 42 and a terminal 41 are bonded, after which a case 47 is attached and the semiconductor element 1 is sealed with gel 46 to fabricate a semiconductor device.

The semiconductor device fabricated in this manner has been subjected to 50000 cycles of a power cycle test under conditions of a 150° C. high-temperature holding test for 1000 h, Tjmax150° C., and ΔTj 100° C. At the test, a case of a decrease in a bonding area of the device after the test being within 10% is evaluated as “o”, while a case of the bonding area of the device decreasing more than 10% is evaluated as “x” (FIG. 10). This deterioration in bonding is confirmed by observation of an ultrasonic image and cross-sections.

As a result, in all of the fifth to eighth examples, any degrading phenomenon, such as separation, has been not found at a reaction portion after the reliable test. Although a few creep voids have been found, the sufficient bonding reliability of the device has been confirmed.

Next, in first and second comparative example of FIG. 11, the Sn-based lead-free solder 9 has been given the same composition of Sn-3Ag-0.5Cu and a semiconductor device has been fabricated under a condition that separation of the layer of the (Ni, Cu)3Sn4 compound 13 from the interface occurs, that the Sn—V compound layer is present, and that the unreacted Ni—V layer is not present and fabricated under the condition contrary to the above condition, and then the semiconductor device has been subjected to a reliability test. In the first comparative example of FIG. 11, separation has occurred at a bonding portion of the device in both the high-temperature holding test and the power cycle test, which, therefore, give respective evaluation results “x”. In the second comparative example of FIG. 11, the high-temperature holding test gives an evaluation result “o” but the power cycle test, in which separation has occurred at a reaction portion interface, gives an evaluation result “x”. This leads to an understanding that in the embodiment of FIG. 8, the reliability of the device is damaged unless both the Sn—V compound 12 and the unreacted Ni—V layer 7 are left intact.

In third and fourth comparative examples of the table of FIG. 11, a semiconductor device has been fabricated by the same method as executed in the fifth to eighth examples of FIG. 10, and the reliability test has been conducted. In the third comparative example of FIG. 11, separation has occurred at a bonding portion of the device in both the high-temperature holding test and the power cycle test, which, therefore, give respective evaluation results “x”. In the fourth comparative example of FIG. 11, the high-temperature holding test gives an evaluation result “o” but the power cycle test, in which separation has occurred at a reaction portion interface, gives an evaluation result “x”. This leads to an understanding that in the embodiment of FIG. 9, the reliability of the device is damaged unless both the Sn—V compound 12 and the unreacted Ni—V layer 7 are left intact.

As described above, the test results of FIGS. 10 and 11 demonstrate that in a state where the semiconductor element and a conductor are bonded by the Sn-based lead-free solder, leaving both the Sn—V compound 12 and the unreacted Ni—V layer 7 intact ensures the reliability of the device in both cases of holding the bonding under the high-temperature service environment at 150° C. and enduring power cycles.

In the present invention, the example in which the layer of the (Ni, Cu)3Sn4 compound 13 is formed by using the Sn-based lead-free solder containing Cu has been described. When Sn-based lead-free solder containing no Cu is used, a layer of an Ni3Sn4-based compound is formed, which offers the same effects.

The one embodiment of the present invention described above offers the following effects.

(1) The semiconductor device includes the semiconductor element 1 having the Ni—V electrode 7 and the conductors 31 and 32, the semiconductor element 1 and the conductors 31 and 32 being bonded via the Sn-based lead-free solder 9. In the semiconductor device, the Sn—V compound layer 13 and the (Ni, Cu) 3Sn4 compound layer 4 or the Ni3Sn4 compound layer that is adjacent to the Sn—V compound 13 are formed adjacent to the interface between the semiconductor element 1 and the Sn-based lead-free solder 9. The semiconductor device structured in this manner can be provided as a semiconductor device with improved bonding reliability.

(2) In the semiconductor device, the Sn—V compound layer 13 is a layer formed as a result of reaction of a part of the Ni—V electrode 7 with the Sn-based lead-free solder 9. This improves the bonding reliability of the device.

(3) In the semiconductor device, the (Ni, Cu)3Sn4 compound layer 4 or the Ni3Sn4 compound layer is disposed adjacent to the interface along the entire part of the Sn—V compound layer 13. This allows an improvement in the bonding strength of the device.

(4) The average thickness of the (Ni, Cu)3Sn4 compound layer 4 or the Ni3Sn4 compound layer of the semiconductor device is 2 μm or more. The semiconductor device structured in this manner can be provided as a semiconductor device with improved bonding reliability.

(5) An unreacted layer of the Ni—V electrode 7 of the semiconductor device, the unreacted layer having not reacted with the Sn-based lead-free solder 9, has an average thickness of 300 nm or more. Because of this, a semiconductor device with improved bonding reliability corresponding to 10-year guarantee of an automobile can be provided.

(6) In the semiconductor device, when the semiconductor element 1 having the Ni—V electrode 7 is bonded to the conductors 31 and 32 by the Sn-based lead-free solder 9, the Sn-based lead-free solder 9 and the Ni—V electrode 7 are caused to react with each other to form the Sn—V layer 12 and the (Ni, Cu)3Sn4 compound layer 4 or the Ni3Sn4 compound layer at a location adjacent to the interface between the semiconductor element 1 and the Sn-based lead-free solder 9, and, following formation of the Sn—V layer 12, an unreacted layer of the Ni—V electrode 7, the unreacted layer having not reacted with the Sn-based lead-free solder 9, is left intact. This provides the semiconductor device of the present invention.

It should be noted that the present invention is not limited to the above embodiment, and various modifications and other configurations may be combined on the condition that such a combination does not depart from the substance of the present invention. In addition, the present invention is not limited to an embodiment that includes all the configurations described in the above embodiment, and includes also an embodiment from which some configurations are deleted.

### REFERENCE SIGNS LIST

1 semiconductor element
2 Al-based electrode
3 Ti-based electrode, Ti layer
4 (Ni, Cu)3Sn4 compound
5 Sn-3Ag-0.5Cu solder
6 Ni-based electrode
7 Ni—V electrode
8 Cu film
9 Sn-based lead-free solder
10 Cu6Sn5-based compound
11 Ni3Sn4-based compound
12 Sn—V compound
13 (Ni, Cu)3Sn4 compound
21 creep void
31 emitter side lead
32 collector side lead
33 resin
41 terminal
42 aluminum wire
43 ceramic substrate
44 Sn-based lead-free solder
45 heat-dissipating base
46 gel
47 case

1. A semiconductor device comprising a semiconductor element having an Ni—V electrode and a conductor, the semiconductor element and the conductor being bonded via Sn-based lead-free solder,
wherein an Sn—V compound layer and an (Ni, Cu)3Sn4 compound layer or an Ni3Sn4 compound layer adjacent to the Sn—V compound are formed adjacent to an interface between the semiconductor element and the Sn-based lead-free solder.

2. The semiconductor device according to claim 1, wherein the Sn—V compound layer is a layer formed as a result of reaction of a part of the Ni—V electrode with the Sn-based lead-free solder.

3. The semiconductor device according to claim 1, wherein the (Ni, Cu)3Sn4 compound layer or the Ni3Sn4 compound layer is disposed adjacent to the interface along entire part of the Sn—V compound layer.

4. The semiconductor device according to claim 1, wherein an average thickness of the (Ni, Cu)3 Sn4 compound layer or the Ni3 Sn4 compound layer is 2 μm or more.

5. The semiconductor device according to claim 2, wherein an unreacted layer of the Ni—V electrode, the unreacted layer having not reacted with the Sn-based lead-free solder, has an average thickness of 300 nm or more.

6. A manufacturing method for a semiconductor device by which a semiconductor element having an Ni—V electrode is bonded to a conductor by Sn-based lead-free solder, the manufacturing method comprising:
causing the Sn-based lead-free solder and the Ni—V electrode to react with each other to form an Sn—V layer and an (Ni, Cu)3 Sn4 compound layer or an Ni3 Sn4 compound layer at a location adjacent to an interface between the semiconductor element and the Sn-based lead-free solder; and
following formation of the Sn—V layer, leaving an unreacted layer of the Ni—V electrode, the unreacted layer having not reacted with the Sn-based lead-free solder, intact.
